(19) United States
(12) Patent Application Publication
(10) Pub. No.: US 2015/0179811 A1
(43) Pub. Date: Jun. 25, 2015

(54) THIN FILM TRANSISTOR AND METHOD OF MANUFACTURING THE SAME, AND DISPLAY UNIT AND ELECTRONIC APPARATUS

(71) Applicant: Sony Corporation, Tokyo (JP)

(72) Inventors: Michihiro Kanno, Kanagawa (JP); Takahiro Kawamura, Kanagawa (JP)

(73) Assignee: Sony Corporation, Tokyo (JP)

(21) Appl. No.: 14/419,134

(22) PCT Filed: Aug. 2, 2013
(86) PCT No.: PCT/JP2013/004696

§ 371 Date: Feb. 2, 2015

(30) Foreign Application Priority Data
Aug. 13, 2012 (JP) 2012-179520

(51) Int. Cl. H01L 29/786; H01L 29/66; H01L 29/423

(52) U.S. Cl. CPC H01L 29/78609; H01L 29/42384; H01L 29/7869; H01L 29/78669; H01L 29/78678; H01L 29/66765; H01L 29/66969

(57) ABSTRACT

There are provided a thin film transistor having a simple structure that allows reduction in leakage current at the time of gate negative bias, and a method of manufacturing the thin film transistor, and a display unit and an electronic apparatus. The thin film transistor includes: a gate electrode; a semiconductor film including a channel region that faces the gate electrode; and an insulating film provided at least at a position near an end portion on the gate electrode side of side walls of the semiconductor film.

### TECHNICAL FIELD

The present technology relates to a thin film transistor (TFT) having a bottom-gate structure and a method of manufacturing the same, and a display unit and an electronic apparatus which include the thin film transistor.

### BACKGROUND ART

In a thin film transistor at the time of gate off, a leakage current (off-state current) may flow between source and drain electrodes. If a large amount of such an off-state current flows in a thin film transistor configuring a display unit, unlit spots and bright spots are generated, and defects in characteristics such as unevenness and roughening occur on the panel, thereby lowering the reliability. The off-state current is caused mainly by generation of career due to a high electric field region between a source and a channel and between a drain and the channel, and is significant in a state of gate negative bias.

On the other hand, securing the on-state current is also important in terms of response speed and securing of driving current. In view of this, a thin film transistor having a high on/off ratio is desired, and for example, PTLs 1 to 3 propose various LDD (lightly doped drain) structures as methods of suppressing the off-state current without decreasing the on-state current.

### CITATION LIST

### Patent Literature

### [PTL 1]

Japanese Unexamined Patent Application Publication No. 2002-313808

### [PTL 2]

Japanese Unexamined Patent Application Publication No. 2010-182716

### [PTL 3]

Japanese Unexamined Patent Application Publication No. 2008-258345

### SUMMARY

However, since such thin film transistors having LDD structures have complicated structures, variation tends to be caused in manufacturing process.

It is therefore desirable to provide a thin film transistor having a simple structure that allows reduction in leakage current at the time of gate negative bias, and a method of manufacturing the thin film transistor, and a display unit and an electronic apparatus.

According to an embodiment of the present technology, there is provided a thin film transistor including: a gate electrode; a semiconductor film including a channel region that faces the gate electrode; and an insulating film provided at least at a position near an end portion on the gate electrode side of side walls of the semiconductor film.

According to an embodiment of the present technology, there is provided a display unit provided with a plurality of devices and a thin film transistor that drives the plurality of devices. The thin film transistor includes: a gate electrode; a semiconductor film including a channel region that faces the gate electrode; and an insulating film provided at least at a position near an end portion on the gate electrode side of side walls of the semiconductor film.

According to an embodiment of the present technology, there is provided an electronic apparatus including a display unit provided with a plurality of devices and a thin film transistor that drives the plurality of devices. The thin film transistor includes: a gate electrode; a semiconductor film including a channel region that faces the gate electrode; and an insulating film provided at least at a position near an end portion on the gate electrode side of side walls of the semiconductor film.

In the thin film transistor according to the embodiment of the present technology, with the insulating film provided on a side wall of the semiconductor film at an end portion on the gate electrode side, a high electric field region at the time of gate negative bias is distanced from the semiconductor film.

According to an embodiment of the present technology, there is provided a method of manufacturing a thin film transistor. The method includes: forming a gate electrode on a substrate; forming a semiconductor film on the gate electrode, the semiconductor film including a channel region that faces the gate electrode; and forming an insulating film at least at a position near an end portion on the gate electrode side of side walls of the semiconductor film.

According to the thin film transistor and the method of manufacturing the same, and the display unit and the electronic apparatus of the embodiments of the present technology, since the insulating film is provided on the semiconductor film at the end portion of the side wall on the gate electrode side, it is possible to distance the semiconductor film and the high electric field region from each other. Consequently, the electric field of semiconductor film is moderated, and it is possible to reduce leakage current at the time of gate negative bias.

It is to be understood that both the foregoing general description and the following detailed description are exemplary, and are intended to provide further explanation of the technology as claimed.

### BRIEF DESCRIPTION OF DRAWINGS

The accompanying drawings are included to provide a further understanding of the disclosure, and are incorporated in and constitute a part of this specification. The drawings illustrate embodiments and, together with the specification, serve to explain the principles of the technology.

[FIG. 1A]

FIG. 1A is a plan view showing a structure of a thin film transistor according to a first embodiment of the present technology.

[FIG. 1B]

FIG. 1B is a sectional view of the thin film transistor illustrated in FIG. 1A.

[FIG. 2A]

FIG. 2A is a sectional view showing a method of manufacturing the thin film transistor illustrated in FIG. 1B in the order of steps.

[FIG. 2B]

FIG. 2B is a sectional view showing a step subsequent to the step of FIG. 2A.

[FIG. 2C]

FIG. 2C is a sectional view showing a step subsequent to the step of FIG. 2B.

[FIG. 2D]

FIG. 2D is a sectional view showing a step subsequent to the step of FIG. 2C.

[FIG. 2E]

FIG. 2E is a sectional view showing a step subsequent to the step of FIG. 2D.

[FIG. 3]

FIG. 3 is a sectional view of a display unit including the thin film transistor illustrated in FIG. 1B.

[FIG. 4]

FIG. 4 is a view showing a general configuration of the display unit illustrated in FIG. 3.

[FIG. 5]

FIG. 5 is a circuit diagram showing an example of a pixel driving circuit illustrated in FIG. 4.

[FIG. 6]

FIG. 6 is a characteristic chart showing relationship between a current and a voltage in a dark state.

[FIG. 7]

FIG. 7 is a sectional view of a thin film transistor according to a second embodiment of the present technology.

[FIG. 8A]

FIG. 8A is a sectional view showing a method of manufacturing the thin film transistor illustrated in FIG. 7 in the order of steps.

[FIG. 8B]

FIG. 8B is a sectional view showing a step subsequent to the step of FIG. 8A.

[FIG. 9A]

FIG. 9A is a plan view showing a structure of a thin film transistor according to modification 1.

[FIG. 9B]

FIG. 9B is a sectional view of the thin film transistor illustrated in FIG. 9A.

[FIG. 10]

FIG. 10 is a sectional view showing a structure of a thin film transistor according to a modification 2.

[FIG. 11A]

FIG. 11A is a sectional view showing an exemplary structure of a thin film transistor according to a modification 3.

[FIG. 11B]

FIG. 11B is a sectional view showing another exemplary structure of the thin film transistor according to the modification 3.

[FIG. 11C]

FIG. 11C is a sectional view showing still another exemplary structure of the thin film transistor according to the modification 3.

[FIG. 11D]

FIG. 11D is a sectional view showing still another exemplary structure of the thin film transistor according to the modification 3.

[FIG. 12]

FIG. 12 is a perspective view showing an external appearance of an application example 1 of the thin film transistor according to any of the above-mentioned embodiments and so forth.

[FIG. 13A]

FIG. 13A is a perspective view showing an external appearance of an application example 2 as viewed from a front side.

[FIG. 13B]

FIG. 13B is a perspective view showing an external appearance of the application example 2 as viewed from a rear side.

[FIG. 14]

FIG. 14 is a perspective view showing an external appearance of an application example 3.

[FIG. 15]

FIG. 15 is a perspective view showing an external appearance of an application example 4.

[FIG. 16A]

FIG. 16A shows a front view, a left side view, a right side view, a top view, and a bottom view of an application example 5 in a folded state.

[FIG. 16B]

FIG. 16B shows a front view and a side view of the application example 5 in an unfolded state.

### DESCRIPTION OF EMBODIMENTS

In the following, embodiments of the present technology will be described in detail with reference to the drawings. It is to be noted that description will be made in the following order.
1. First Embodiment (an example where a side wall and a total light shield structure are adopted)
   1-1. General Configuration
   1-2. Manufacturing Method
   1-3. Display unit
   1-4. Function and Effect
2. Second Embodiment (an example where a rectangular insulating film and a total light shield structure are adopted)
3. Modification 1 (an example where a side wall and a partial light shield structure are adopted)
4. Modification 2 (an example where a rectangular insulating film and a partial light shield structure are adopted)
5. Modification 3 (an example where a channel protective film is provided on a semiconductor film)
6. Application Examples

### First Embodiment

### 1.1 General Configuration

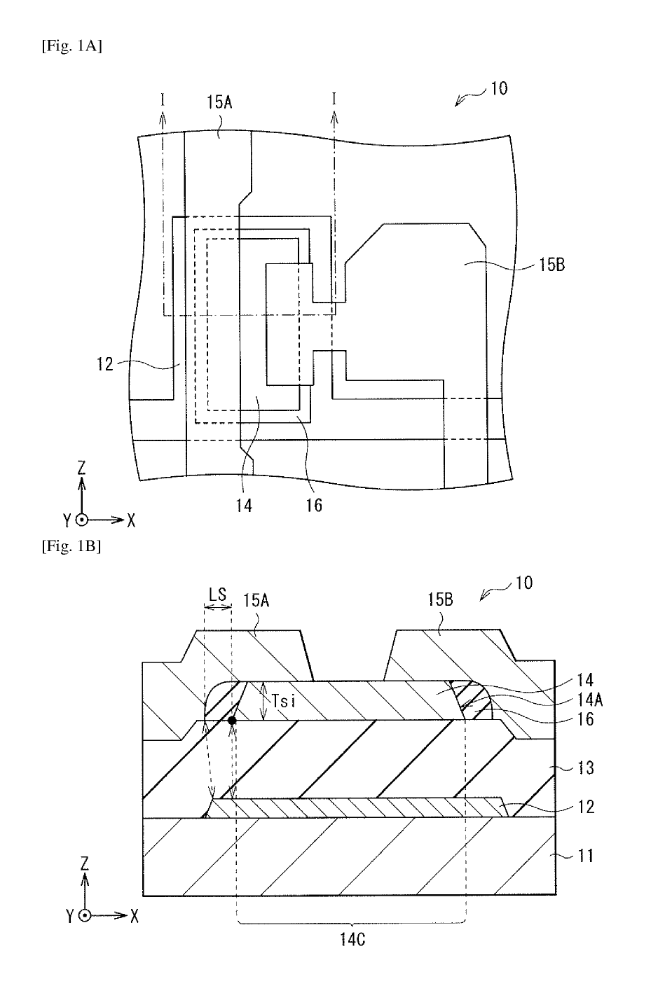

FIG. 1A shows a planar configuration of a bottom-gate type (inversely-staggered type) thin film transistor (thin film transistor 10) according to a first embodiment of the present disclosure, and FIG. 1B schematically shows a cross-sectional configuration of the thin film transistor 10 taken along an I-I dashed-dotted line illustrated in FIG. 1A. The thin film transistor 10 is a TFT employing, for example, polysilicon or the like as a semiconductor film 14, and is used as a drive device of an organic EL display or the like, for example. The thin film transistor 10 includes a gate electrode 12, a gate insulating film 13, the semiconductor film 14 forming a channel region 14C, and a pair of source and drain electrodes (a source electrode 15A and a drain electrode 15B) which are provided on a substrate 11 in this order. In the present embodiment, an insulating film 16 is provided on a side face 14A of the semiconductor film 14. In addition, the semiconductor film 14 has a planar dimension smaller than that of the gate electrode 12. In other words, the semiconductor film 14 is totally covered by the gate electrode 12 as viewed from the substrate 11 side. Specifically, when the thin film transistor 10 is used in a liquid crystal display unit, light, such as backlight, emitted from a rear side is totally blocked by the gate electrode 12 (total light shield structure).

The substrate 11 is configured of a glass substrate, a plastic film, or the like. Examples of the plastic material include, for example, PET (polyethylene terephthalate) and PEN (polyethylene naphthalate). If it is possible to form the semiconductor film 14 by a sputtering method or the like without heating the substrate 11, then it is possible to use an inexpensive plastic film to form the substrate 11. Alternatively, it is also possible to use a metal sheet made of stainless-steel, aluminum (Al), copper (Cu), or the like whose surface has been subjected to insulation treatment.

The gate electrode 12 has a role to apply a gate voltage to the thin film transistor 10, and to control the career density in the semiconductor film 14 with use of the gate voltage. The gate electrode 12 is provided in a selective region on the substrate 11, and is configured of a metal such as platinum (Pt), titanium (Ti), ruthenium (Ru), molybdenum (Mo), Cu, tungsten (W), nickel (Ni), Al, and tantalum (Ta), or an alloy thereof, for example. Alternatively, it is also possible to use two or more of the just-mentioned metals in a laminated manner.

The gate insulating film 13 is provided between the gate electrode 12 and the semiconductor film 14, and has a thickness of about 50 nm to about 1 micrometer both inclusive. The gate insulating film 13 is configured of an insulating film which includes one or more of a silicon oxide film (SiO), a silicon nitride film (SiN), a silicon oxynitride film (SiON), a hafnium oxide film (HfO), an aluminum oxide film (AlO), an aluminum nitride film (AlN), a tantalum oxide film (TaO), a zirconium oxide film (ZrO), a hafnium oxynitride film, a hafnium silicon oxynitride film, an aluminum oxynitride film, a tantalum oxynitride film, and a zirconium oxynitride film, for example. The gate insulating film 13 may have a single layer structure, or a lamination structure using two or more materials such as SiN and SiO. When the gate insulating film 13 has a lamination structure, it is possible to enhance the characteristic of the interface between the gate insulating film 13 and the semiconductor film 14, and to effectively suppress mixing of impurities (for example, water) from outside air into the semiconductor film 14. The gate insulating film 13 is patterned into a predetermined form by etching after application and formation, but depending on the material, the gate insulating film 13 may be formed into a pattern by printing technique such as ink-jet printing, screen printing, offset printing, and gravure printing.

The semiconductor film 14 is provided in a form of an island on the gate insulating film 13, and is provided with the channel region 14C at a position in facing relation to the gate electrode 12 between the pair of the source electrode 15A and the drain electrode 15B. The semiconductor film 14 is made of a polysilicon, an amorphous silicon, or an oxide semiconductor which contains, as main component, an oxide of one or more of elements of In, Ga, Zn, Sn, Al, and Ti, for example. Specifically, for example, zinc oxide (ZnO), indium tin oxide (ITO), In—M—Zn—O (where M is one or more of Ga, Al, Fe, and Sn), and the like may be used. The semiconductor film 14 has a thickness of about 20 nm to about 100 nm both inclusive, for example.

In addition, examples of the material of the semiconductor film 14 include, other than the above-mentioned materials, for example, organic semiconductor materials such as peri-Xanthenoxanthene (PXX) derivative. Examples of the organic semiconductor materials include, for example, polythiophene, poly-3-hexyl thiophene <P3HT> which is obtained by addition of a hexyl group to a polythiophene, pentacene <2,3,6,7-dibenzo anthracene>, polyanthracene, naphthacene, hexacene, heptacene, dibenzo pentacene, tetrabenzo pentacene, chrysene, perylene, coronene, terrylene, ovalene, quaterrylene, circumanthracene, benzopyrene, dibenzopyrene, triphenylene, polypyrrole, polyaniline, polyacetylene, polydiacetylene, polyphenylene, polyfuran, polyindole, polyvinyl carbazole, polyselenophene, polytellurophene, polyisothianaphthene, polycarbazole, polyphenylene sulfide, polyphenylenevinylene, polyphenylene sulfide, polyvinylene sulfide, polythienylenevinylene, polynaphthalene, polypyrene, polyazulene, phthalocyanine represented by copper phthalocyanine, merocyanine, hemicyanin, polyethylene dioxythiophene, pyridazine, naphthalene tetra carboxylic diimide, poly(3,4-ethylenedioxythiophene)/polystyrene sulfonate <PEDOT/PSS>, 4,4′-biphenyl dithiol (BPDT), 4,4′-diisocyanate biphenyl, 4,4′- diisocyanate-p-terphenyl, 2,5-bis(5′-thioacetyl-2′-thiophenyl) thiophene, 2,5-bis(5′-thioacetoxyl-2′1-thiophenyl) thiophene, 4,4′-diisocyanate phenyl, benzidine (biphenyl-4, 4′-diamine), TCNQ (tetracyanoquinodimethane), tetrathiafulvalene (TTF)-TCNQ complex, bis-ethylene tetrathiafulvalene (BEDTTTF)-perchloric acid complex, BEDTTTF-iodine complex, charge-transfer complex represented by TCNQ-iodine complex, biphenyl-4,4′-dicarboxylic acid, 1,4-di(4-thiophenyl acetylenyl)-2-ethylbenzene, 1,4-di(4-isocyanate phenyl acetylenyl)-2-ethylbenzene, dendrimer, fullerenes C60, C70, C76, C78, C84 etc., 1,4-di(4-thiophenyl ethynyl)-2-ethylbenzene, 2,2″-dihydroxy-1,1′: 4′,1″-terphenyl, 4,4′-biphenyl diethanal, 4,4′-biphenyldiol, 4,4′-biphenyl diisocyanate, 1,4-diacetylenebenzene, diethylbiphenyl-4,4′ dicarboxylate, benzo<1, 2-c;3,4-c′;5, 6-c″>tris<1,2>dithiol-1,4,7-trithione, alpha-sexithiophene, tetrathiotetracene, tetraselenotetracene, tetratelluriumtetracene, poly(3-alkyl thiophene), poly(3-thiophene-beta-ethanesulfonic acid), poly(N-alkyl pyrrole) poly(3-alkyl pyrrole), poly(3,4-dialkyl pyrrole), poly(2,2′-thienyl pyrrole), poly(dibenzo thiophene sulfide), and quinacridone. Further, in addition thereto, condensed polycyclic aromatic compounds, porphyrin derivatives, and compounds selected from a group composed of phenyl vinylidene-based conjugated system oligomers and thiophene-based conjugated system oligomers. Furthermore, it is also possible to use materials obtained by mixing organic semiconductor materials with insulating high polymer materials.

In the present embodiment, the insulating film 16 is provided on the side face 14A of the semiconductor film 14 as described above. Although details are described later, the insulating film 16 is provided in a side wall form after the semiconductor film 14 is formed. Examples of the material of the insulating film 16 include, for example, SiO₂, SiN, and SiON, and in particular, when a material different from that of the gate insulating film serving as the foundation is used, an uniform film is easily formed.

The width (Ls) of the insulating film 16, that is, a distance between the semiconductor film 14 and an interface of the source electrode 15A or the drain electrode 15B is preferably distanced from each other as much as possible. Specifically, the width (Ls) of the insulating film 16 is preferably about 1% to about 200% both inclusive, of the film thickness (Tsi) in the lamination direction (Y direction) of the semiconductor film 14, in other words, about 2 nm to about 300 nm both inclusive. In addition, more preferably, the width (Ls) is about 5% to about 100% both inclusive, of the film thickness (Tsi) of the semiconductor film 14, that is, about 5 nm to about 200 nm both inclusive. With this configuration, it is possible to distance the high electric field regions generated between the gate electrode 12 and the source electrode 15A and between the gate electrode and the drain electrode 15B, from the semiconductor film 14. Consequently, the electric field in the semiconductor film 14 at the time of gate off (0 V or gate negative bias) is moderated, thereby reducing leakage of current.

It should be noted that, while the insulating film 16 is provided on the entire side faces of the semiconductor film 14 in the present embodiment, this is not limitative, and it is only necessary that the insulating film 16 is provided at least at the lower end on the gate electrode 12 side, in other words, at a position near the interface between the semiconductor film 14 and the gate insulating film 13. In addition, although it is preferable to form the insulating film 16 on the entire outer periphery side face of the semiconductor film 14 patterned as illustrated in FIG. 1A, the above-described effect is also obtained by providing the insulating film 16 only on the side face of the semiconductor film 14 parallel to the extending direction (Z direction) of the gate electrode 12, for example.

The pair of the source electrode 15A and the drain electrode 15B are provided on the semiconductor film 14 as separated from each other, and are electrically connected to the semiconductor film 14. The source electrode 15A and the drain electrode 15B may be configured of a single layer film made of a material similar to that of the gate electrode 12, for example, Al, Mo, Ti, Cu, or the like, or a laminated film made of two or more of these materials.

The thin film transistor 10 is manufactured as described below, for example.

### 1-2. Manufacturing Method

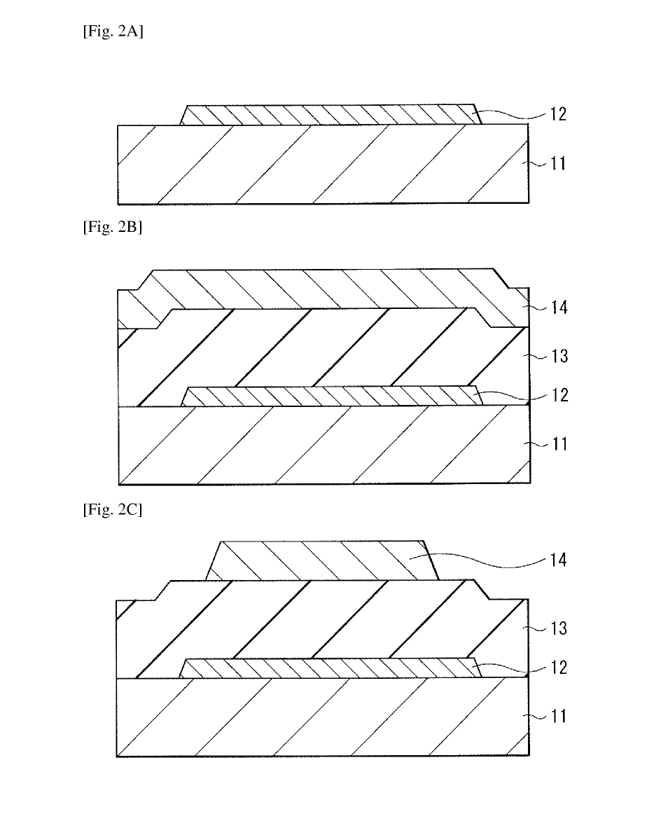

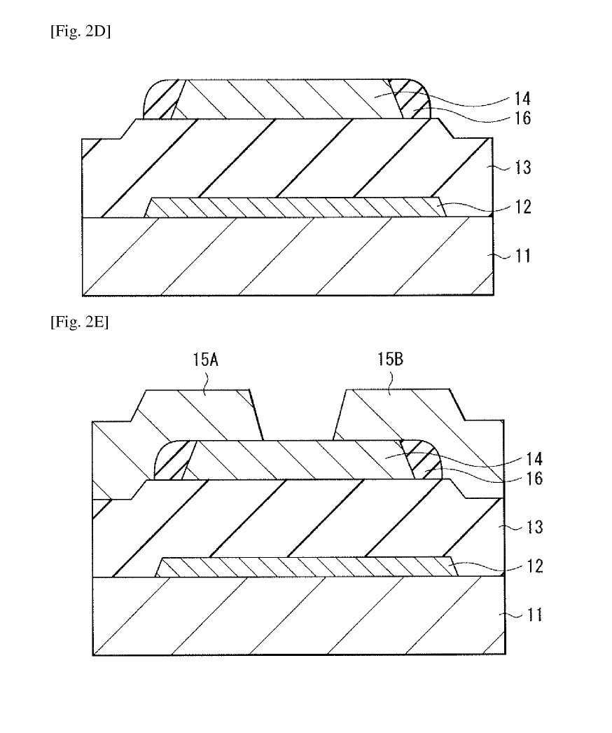

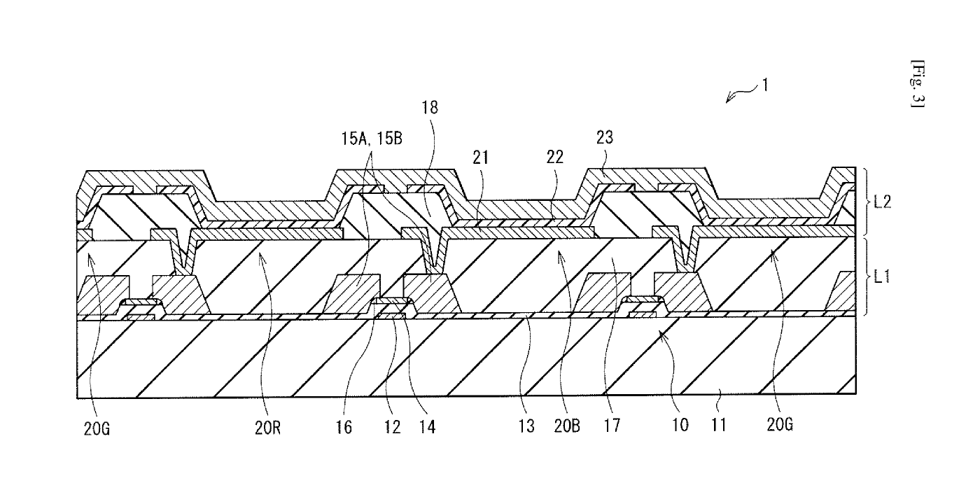

First, as illustrated in FIG. 2A, a metal film that serves as the gate electrode 12 is formed on the entire surface of the substrate 11 by methods such as the sputtering method and the vacuum deposition method. Next, this metal film is patterned by, for example, photolithography and etching to form the gate electrode 12.

Subsequently, as illustrated in FIG. 2B, the gate insulating film 13 and the semiconductor film 14 are formed in order on the entire surface of the substrate 11 and the gate electrode 12. Specifically, a silicon oxide film is formed on the entire surface of the substrate 11 by, for example, the plasma chemical vapor deposition (PECVD) method to form the gate insulating film 13. The sputtering method may be used to form the gate insulating film 13. Then, the semiconductor film 14 made of, for example, amorphous silicon is formed on the gate insulating film 13. To form the semiconductor film 14, amorphous silicon is formed on the gate insulating film 13 by, for example, the DC (direct current) sputtering method.

Subsequently, the semiconductor film 14 is patterned by photolithography and etching as illustrated in FIG. 2C. It should be noted that the semiconductor film 14 may be formed also by the RF (radio frequency; high frequency) sputtering method or the like when an oxide semiconductor material is used as the material of the semiconductor film 14, but the DC sputtering method is preferably used in terms of deposition speed.

Then, as illustrated in FIG. 2D, the insulating film 16 is formed on side faces of the semiconductor film 14. Specifically, a film is formed with use of, for example, the CVD method, and then an etch back process is used to form the insulating film 16 having a side wall form.

Subsequently, as illustrated in FIG. 2E, the pair of the source electrode 15A and the drain electrode 15B is formed by, for example, the photolithographic etching. Specifically, for example, an Al film, a Ti film, and an Al film are formed in order, and on the Al film, a resist (not illustrated) is formed and patterned by the photolithography method to form the source electrode 15A and the drain electrode 15B. Thus, the thin film transistor 10 that includes the insulating film 16 having a side wall form on the side faces of the semiconductor film 14 is completed.

### 1-3. Display Unit

FIG. 3 shows a cross-sectional configuration of a semiconductor unit (in this instance, display unit 1) including the above-mentioned thin film transistor 10 as a drive device. The display unit 1 is a display unit of a self light emitting type which includes a plurality of organic light emitting devices 20R, 20G, and 20B (devices) as light emitting devices. The display unit 1 includes a pixel driving circuit formation layer L1, a light emitting device formation layer L2 including the organic light emitting devices 20R, 20G, and 20B, and an opposed substrate (not illustrated) which are formed on the substrate 11 in this order. The display unit 1 is a top-emission type display unit in which light is extracted from the opposed substrate side, and the pixel driving circuit formation layer L1 includes the thin film transistor 10.

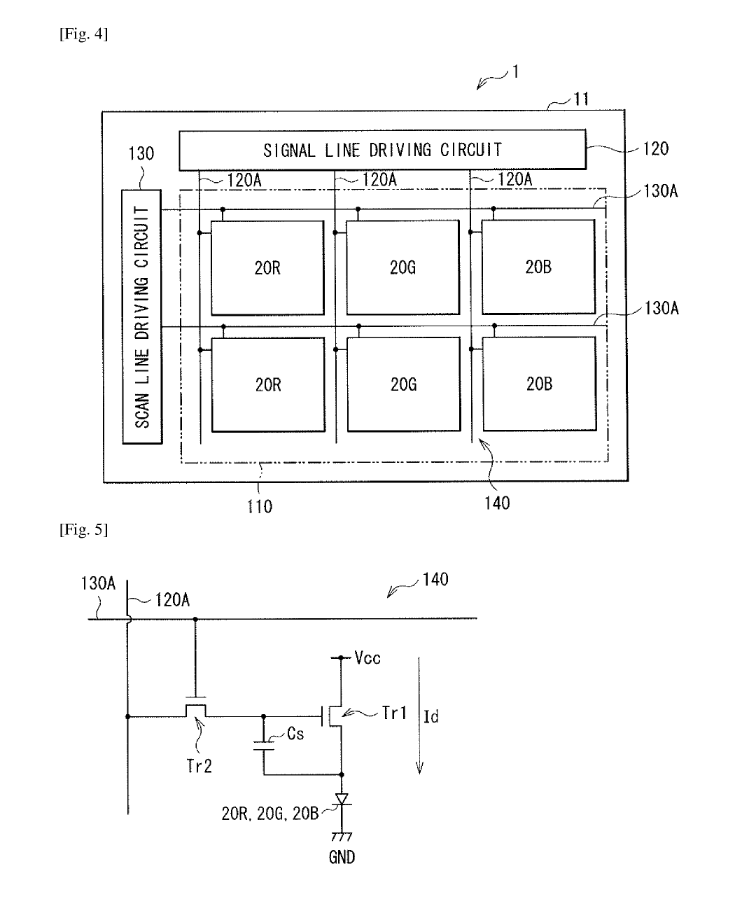

FIG. 4 shows a general configuration of the display unit 1. The display unit 1 is provided with a display region 110 on the substrate 11, and is used as an ultra-thin organic light emission color display unit or the like. For example, a signal line driving circuit 120 and a scan line driving circuit 130, which serve as drivers for image display, are provided around the display region 110 on the substrate 11.

In the display region 110, the plurality of organic light emitting devices 20R, 20G, and 20B that are two-dimensionally disposed in a matrix, and a pixel driving circuit 140 that drives the organic light emitting devices 20R, 20G, and 20B are formed. In the pixel driving circuit 140, a plurality of signal lines 120A are disposed in a column direction, and a plurality of scan lines 130A are disposed in a row direction. The organic light emitting devices 20R, 20G, and 20B are provided at respective intersections of the signal lines 120A and the scan lines 130A. Each of the signal lines 120A is connected to the signal line driving circuit 120, and each of the scan lines 130A is connected to the scan line driving circuit 130.

The signal line driving circuit 120 supplies a signal voltage of a video signal corresponding to luminance information supplied from a signal supply source (not illustrated) to the organic light emitting devices 20R, 20G, and 20B selected through the signal lines 120A.

The scan line driving circuit 130 includes a shift register that sequentially shifts (transfers) a start pulse in synchronization with an inputted clock pulse, and the like. The scan line driving circuit 130 scans the organic light emitting devices 20R, 20G, and 20B on a row unit basis at the time of writing a video signal thereto, and sequentially supplies a scanning signal to each of the scan lines 130A.

The pixel driving circuit 140 is provided in a layer between the substrate 11 and the organic light emitting devices 20R, 20G, and 20B, that is, in the pixel driving circuit formation layer L1. As shown in FIG. 5, the pixel driving circuit 140 is an active type driving circuit which includes a driving transistor Tr1 and a writing transistor Tr2 at least one of which is the thin film transistor 10, a capacitor Cs between the driving transistor Tr1 and the writing transistor Tr2, and the organic light emitting devices 20R, 20G, and 20B.

Next, referring to FIG. 3 again, the configurations of the pixel driving circuit formation layer L1, the light emitting device formation layer L2 etc. are described in detail.

The thin film transistor 10 (the driving transistor Tr1 and the writing transistor Tr2) configuring the pixel driving circuit 140 is formed in the pixel driving circuit formation layer L1, and further, the signal lines 120A and the scan lines 130A are also embedded in the pixel driving circuit formation layer L1. Specifically, the thin film transistor 10 and a planarizing layer 17 are provided on the substrate 11 in this order. The planarizing layer 17 is provided to mainly planarize the surface of the pixel driving circuit formation layer L1, and is made of an insulating resin material such as polyimide.

The light emitting device formation layer L2 is provided with the organic light emitting devices 20R, 20G, and 20B, a device separating film 18, and a seal layer (not illustrated) that covers the organic light emitting devices 20R, 20G, and 20B and the device separating film 18. Each of the organic light emitting devices 20R, 20G, and 20B includes a first electrode 21 serving as an anode electrode, an organic layer 22 including a light emitting layer, and a second electrode 23 serving as a cathode electrode which are sequentially laminated from the substrate 11 side. The organic layer 22 includes, for example, a hole injection layer, a hole transport layer, a light emitting layer, and an electron transport layer which are provided in this order from the first electrode 21 side. The light emitting layer may be provided for each device, or may be shared by the devices. It should be noted that the layers other than the light emitting layer may be provided as necessary. The device separating film 18, which is made of an insulating material, separates the organic light emitting devices 20R, 20G, and 20B into each device, and defines a light emitting region of each of the organic light emitting devices 20R, 20G, and 20B.

The display unit 1 is applicable to a display unit of electronic apparatuses in various fields such as a television, a digital camera, a notebook personal computer, a mobile terminal apparatus such as a mobile phone, and a video camcorder, which display an externally inputted video signal or an internally generated video signal, as an image or a video.

### 1-4. Function and Effect

As described above, in a thin film transistor used as a drive device of a display unit, if a leakage current (off-state current) flowing between source and drain electrodes is increased at the time of gate off (0 V or gate negative bias), then defects such as unlit spots and bright spots of pixels, decrease in image quality such as roughening, burning, and the like occur. In addition, as the number of the thin film transistor in which a leakage current greater than a desired set value flows increases due to variation of leakage current, the number of defective pixels accordingly increases, and this may lead to decrease in manufacturing yield of the display unit. Further, not only in the pixels, but also at the thin film transistors in the peripheral circuit section, increase in leakage current between the source and drain electrodes at the time of gate off causes increase in power consumption. The leakage current is caused mainly by generation of career in a high electric field region between source and drain channels, and is significant at the time of gate negative bias.

Although various thin film transistors are disclosed in PTL 1 to PTL 3 described above in order to solve this issue, there is another issue that variation is caused in the manufacturing process due to the complicated structure, and the manufacturing yield is low.

On the other hand, in a thin film transistor used in a display unit such as a liquid crystal display unit which emits light from a planar surface, career is generated in a semiconductor film by light emitted from a backlight and the like and the reflected light thereof, and a light leakage current is generated. This applies not only to liquid crystal display units, but also to light from a light emitting layer and the reflected light thereof in organic EL display units. Light leakage at the time of gate off affects the display quality similarly to the above-mentioned off-state current. In view of this, generally, occurrence of light leakage is suppressed by providing light shielding films on the upper and lower sides of a semiconductor layer.

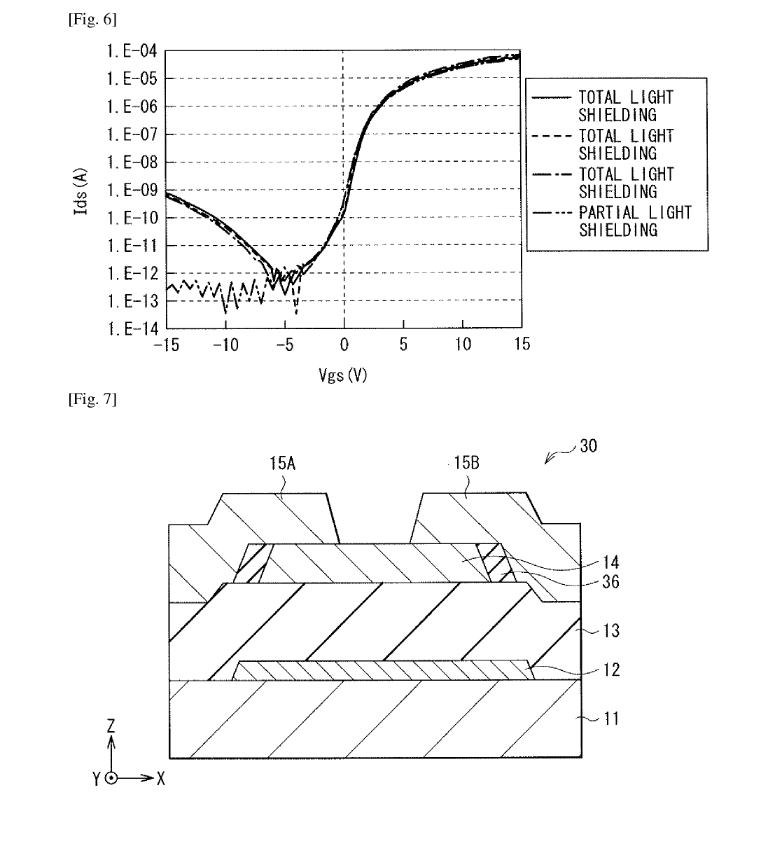

FIG. 6 shows current voltage characteristics in a dark state of a thin film transistor having a total light shield structure and a thin film transistor having a partial light shield structure. Here, the total light shield structure is a structure laid out in such a manner that the gate electrode 12 has a planar dimension larger than that of the semiconductor film 14, as in the present embodiment. When such a structure is adopted, the gate electrode 12 serves also as a light shielding film that blocks light emitted to the semiconductor film 14, thereby making it possible to suppress the above-described light leakage current. Although details are described later, the partial light shield structure is a structure laid out in such a manner that the gate electrode 12 has a planar dimension smaller than that of the semiconductor film 14, and in the partial light shield structure, a part of the semiconductor film 14 is not covered with the gate electrode 12 as viewed from the substrate 11. It is seen that, in the total light shield type thin film transistor, at 0 V or lower, that is, at the time of gate negative bias, leakage current increases. In this case, referring to FIG. 1B, a section which does not include the semiconductor film and is configured only of the gate insulating film is formed between the source and drain electrodes and the gate electrode in a cross-section structure. Consequently, the distance between the source and drain electrodes and the gate electrode is decreased, and an electric field tends to concentrate when a high voltage difference is applied to the section, and this in turn causes an issue that, although a career generated in a semiconductor becomes off leakage, that is, leakage during light emission is suppressed, leakage occurs in a dark state.

In contrast, in the thin film transistor 10 according to the present embodiment, the insulating film 16 having a side wall form is provided on the side faces of the semiconductor film 14. This makes it possible to secure a certain distance between high electric field regions that are generated between the gate electrode 12 and the source electrode 15A and between the gate electrode 12 and the drain electrode 15B, and the end portions of the semiconductor film 14, and thus to distance the high electric field region from the semiconductor film 14.

As described above, in the thin film transistor 10 according to the present embodiment, since the insulating film 16 having a side wall form is provided on the side faces of the semiconductor film 14, it is possible to distance the high electric field regions that are generated between the gate electrode 12 and the source electrode 15A and between the gate electrode 12 and the drain electrode 15B, from the semiconductor film 14. Consequently, without a significant change in the layout of the existing thin film transistor, it is possible to moderate the electric field in the semiconductor film 14, and to reduce the leakage current at the time of negative bias, by a simple structure and manufacturing method. In other words, it is possible to provide a display unit with improved reliability and an electronic apparatus including the display unit.

Next, thin film transistors 30, 40, 50, and 60A to 60D according to a second embodiment and modifications thereof (modifications 1 to 3) will be described. It should be noted that, in the following, components similar to those of the above-mentioned embodiment are denoted by the same reference numerals, and description thereof is appropriately omitted.

### 2. Second Embodiment

FIG. 7 shows a cross-sectional configuration of a bottom-gate type thin film transistor (thin film transistor 30) according to a second embodiment of the present disclosure. The thin film transistor 30 differs from the first embodiment in that an insulating film 36 is provided in parallel along side faces of the semiconductor film 14.

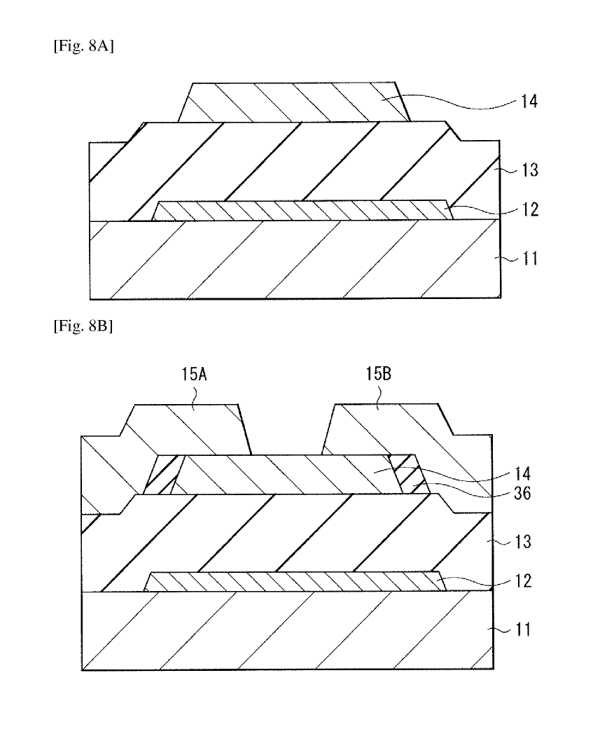

The thin film transistor 30 according to the present embodiment is manufactured as illustrated in FIGS. 8A and 8B, for example. It should be noted that the processes up to the formation of the semiconductor film 14 are similar to those in the above-mentioned first embodiment, and therefore the description thereof is omitted.

First, as illustrated in FIG. 8A, after the films up to the semiconductor film 14 are formed, the semiconductor film 14 is subjected to, for example, low-temperature oxidation (of about 400 deg C when amorphous silicon is used, for example) to form an oxide film on the surface of the semiconductor film 14. Next, the oxide film formed on the top face of the semiconductor film 14 is removed by anisotropic etching to form the insulating film 36 (FIG. 8B).

Thereafter, similarly to the above-mentioned first embodiment, the source electrode 15A and the drain electrode 15B are formed, and the thin film transistor 30 is completed.

It is possible to obtain an effect similar to that of the above-mentioned first embodiment also when the insulating film 36 is formed by oxidizing the semiconductor film 14 in the above-described manner as in the present embodiment. Additionally, since oxidation makes it possible to form the insulating film 36 which is uniform and has only little variation in film thickness, it is possible to bring about an excellent effect of reducing variation in characteristics.

### 3. Modification 1

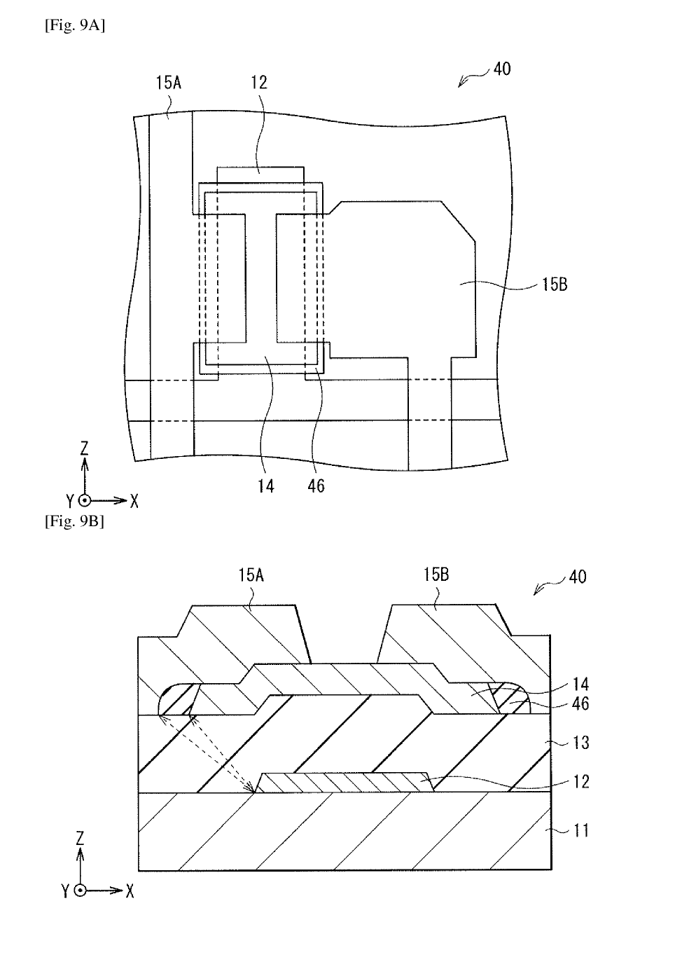

FIG. 9A shows a planar configuration of a thin film transistor (thin film transistor 40) according to a modification (modification 1) of the above-mentioned first embodiment, and FIG. 9B shows a cross-sectional configuration of the thin film transistor 40 taken along a II-II dashed-dotted line shown in FIG. 9A. In the thin film transistor 40, the semiconductor film 14 has a planar dimension larger than that of the gate electrode 12. In other words, the semiconductor film 14 is protruded from the gate electrode 12 as viewed from the substrate 11 side, and the thin film transistor 40 differs from the first embodiment in that a structure (partial light shield structure) is adopted in which light emitted from a rear side and entering the semiconductor film 14 is not totally blocked.

### 4. Modification 2

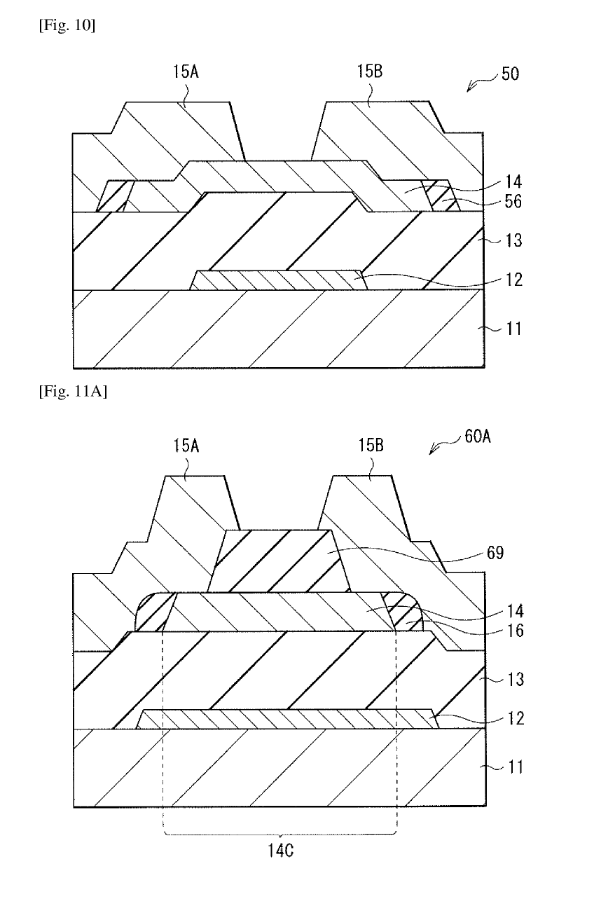

FIG. 10 shows a cross-sectional configuration of a thin film transistor (thin film transistor 50) according to a modification (modification 2) of the above-mentioned second embodiment. The thin film transistor 50 differs from the second embodiment in that a partial light shield structure is adopted similarly to the thin film transistor 40 of the above-mentioned modification 1.

As described above, in the thin film transistors (the thin film transistors 40 and 50) having the partial light shield structure in which the gate electrode 12 has a planar dimension smaller than that of the semiconductor film 14, it is also possible to achieve a function and an effect similar to those of the thin film transistors 10 and 30 according to the above-mentioned first and second embodiments. In addition, when an insulating film 46 is provided, the distance between the gate electrode 12 and the source electrode 15A or the distance between the gate electrode 12 and the drain electrode 15B is increased (l₂<l₁), and thus it is possible to suppress the parasitic capacitance between the gate electrode 12 and the source electrode 15A and between the gate electrode 12 and the drain electrode 15B. It should be noted that the thin film transistors having a partial light shield structure as in the present modifications 1 and 2 are preferably used in, for example, a top-emission type organic EL display unit and a semiconductor unit which has no concern with light shielding.

### 5. Modification 3

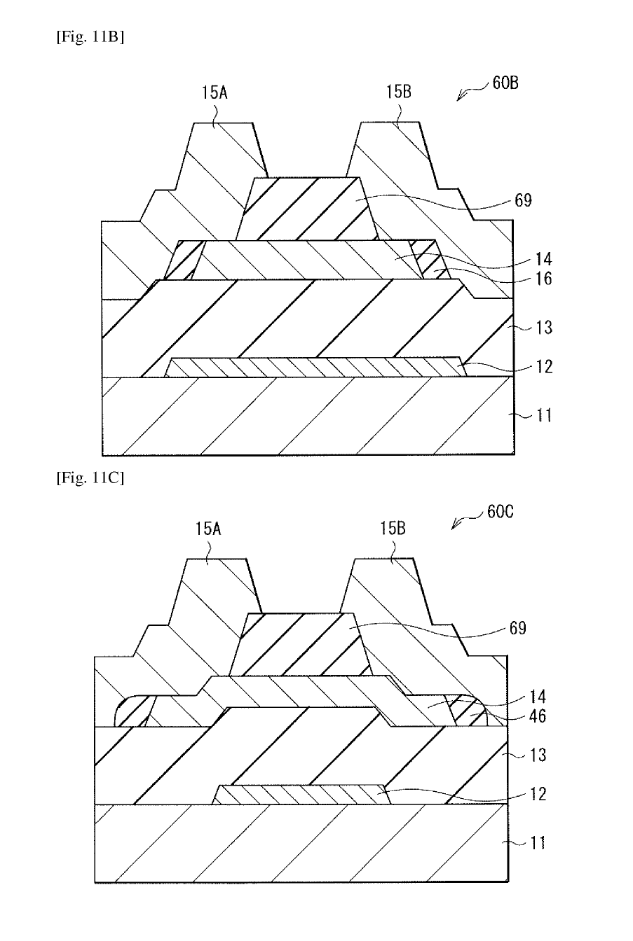

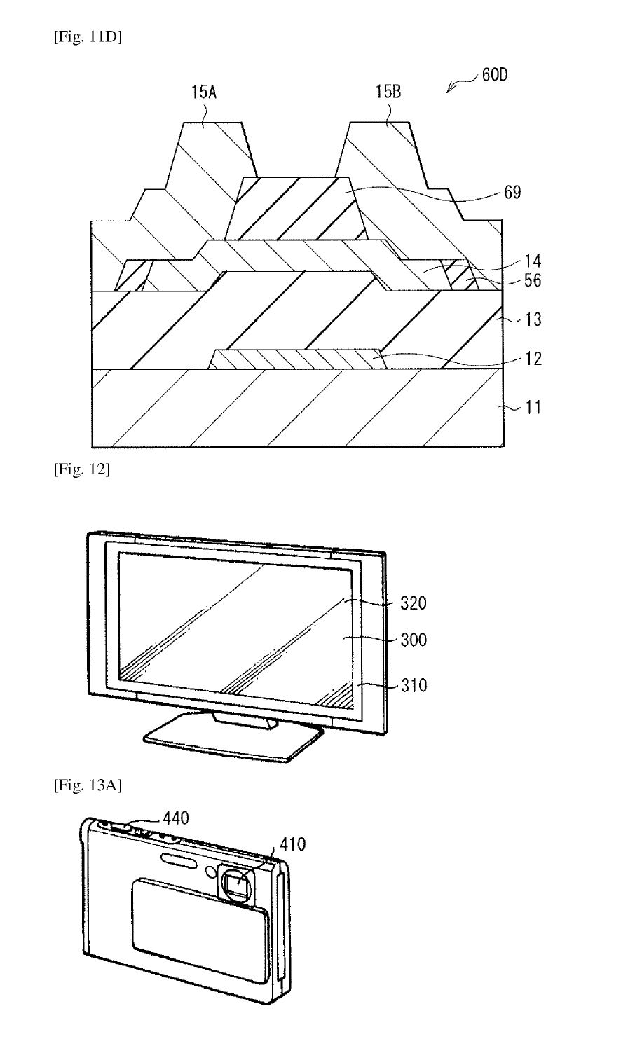

FIG. 11A to FIG. 11D each show a cross-sectional configuration of a thin film transistor (thin film transistors 60A to 60D) according to a modification (modification 3) of the above-mentioned first and second embodiments and the above-mentioned modifications 1 and 2. The thin film transistors 60A to 60D differ from the above-mentioned embodiments and the above-mentioned modifications in that a channel protective film 69 is provided at a position corresponding to the channel region 14C on the semiconductor film 14. It should be noted that the thin film transistors 60A to 60D correspond to the thin film transistors 10, 30, 40, and 50, respectively.

The channel protective film 69 is provided on the semiconductor film 14, and prevents the semiconductor film 14 (in particular, the channel region 14C) from being damaged at the time of forming the source electrode 15A and the drain electrode 15B. The channel protective film 69 is configured of, for example, an aluminum oxide film, a silicon oxide film, or a silicon nitride film. The channel protective film 69 has a thickness of about 150 nm to about 300 nm both inclusive, preferably about 200 nm to about 250 nm both inclusive.

A method of forming the channel protective film 69 is such that an aluminum oxide film is formed on the semiconductor film 14 by, for example, the DC sputtering method, and the aluminum oxide film thus formed is patterned to form the channel protective film 69. Next, a metal thin film is formed in a region including the channel protective film 69 on the semiconductor film 14 by, for example, the sputtering method, and thereafter etching is performed to form the source electrode 15A and the drain electrode 15B. At this time, since the semiconductor film 14 is protected by the channel protective film 69, it is possible to prevent the semiconductor film 14 from being damaged by etching.

As described above, in the present modification, since the channel protective film 69 is provided on the semiconductor film 14, the damage of the semiconductor film 14 caused at the time of forming the source electrode 15A and the drain electrode 15B is suppressed. In addition, it is possible to suppress leakage of oxygen in the case where an oxide semiconductor material is used to form the semiconductor film 14. Further, infiltration of moisture or the like in the atmosphere into the semiconductor film 14 is reduced in the case where an organic semiconductor material is used as the material of the semiconductor film 14. Thus, by providing the channel protective film 69 on the semiconductor film 14, it is possible to prevent degradation in characteristics of the thin film transistor caused by the above-described factors.

### Application Examples

It is possible to favorably use, as a display unit, a semiconductor unit including any of the thin film transistors 10, 30 (30A, 30B, and 30C), 40, 50, and 60A to 60D which are described in the above-mentioned first and second embodiments and the modifications 1 to 3. Examples of the display unit include, for example, a liquid crystal display unit, an organic EL display unit, and an electronic paper display.

### Application Example 1

FIG. 12 shows an external appearance of a television according to application example 1. This television is, for example, provided with an image display screen section 300 including a front panel 310 and a filter glass 320, and the image display screen section 300 corresponds to the above-mentioned display unit.

### Application Example 2

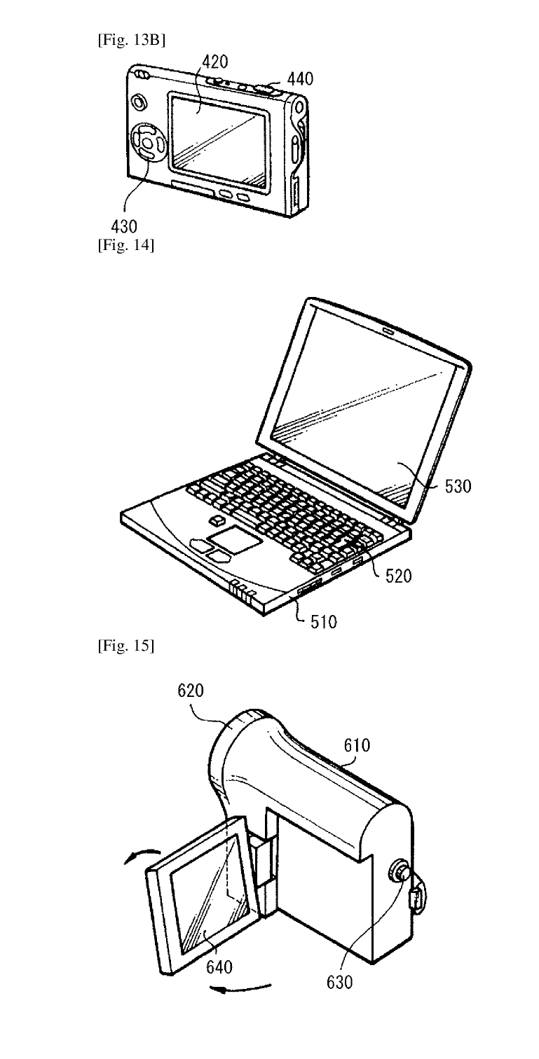

FIG. 13A and FIG. 13B show external appearances of a digital camera according to an application example 2 as viewed from a front side and a rear side, respectively. This digital camera includes, for example, a light emitting section 410 for generating flash light, a display section 420 serving as the above-mentioned display unit, a menu switch 430, and a shutter button 440.

### Application Example 3

FIG. 14 shows an external appearance of a notebook personal computer according to an application example 3. This notebook personal computer includes, for example, a main body 510, a keyboard 520 for inputting letters, etc., and a display section 530 serving as the above-mentioned display unit.

### Application Example 4

FIG. 15 shows an external appearance of a video camcorder according to an application example 4. This video camcorder includes, for example, a main body section 610, a lens 620 which is used to take an image of a subject and is provided on a front side face of the main body section 610, a start-and-stop switch 630 for capturing an image, and a display section 640 serving as the above-mentioned display unit.

### Application Example 5

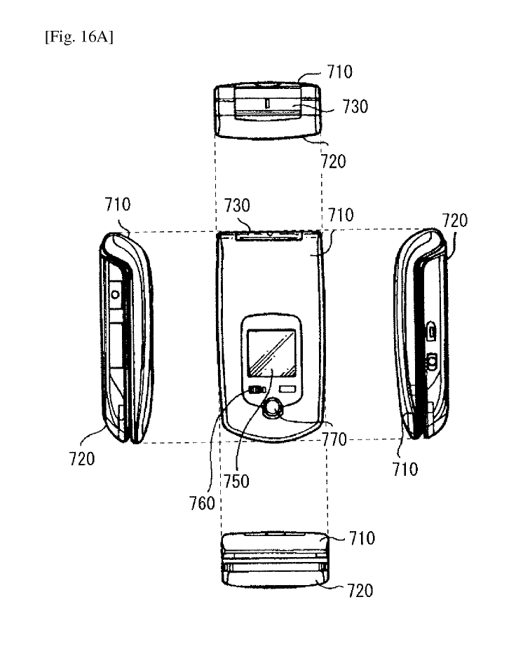

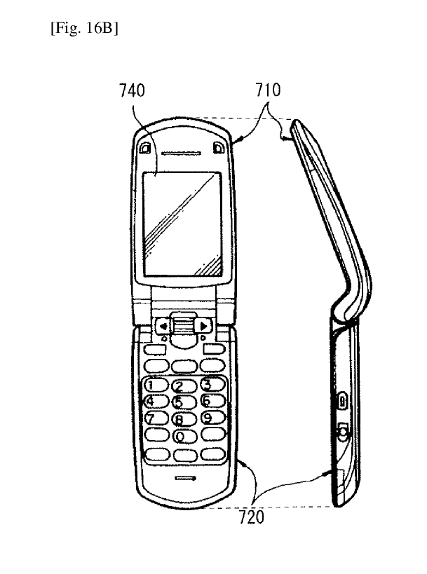

FIG. 16A shows a front view, a left side view, a right side view, a top view, and a bottom view of a mobile phone according to an application example 5 in a folded state. FIG. 16B shows a front view and a side view of the mobile phone in an unfolded state. The mobile phone includes, for example, an upper side housing 710, a lower side housing 720, a coupling section (hinge section) 730 coupling the upper side housing 710 and the lower side housing 720, a display 740, a sub-display 750, a picture light 760, and a camera 770. The display 740 or the sub-display 750 corresponds to the above-mentioned display unit.

Hereinabove, while the description has been made with reference to the first and second embodiments, the modifications 1 to 3, and the application examples, the present disclosure is not limited to the embodiments and so forth, and various modifications may be made. For example, the material and thickness of each layer, the film formation method, the film formation condition, etc. described in the above-mentioned embodiments and the like are not limitative, and other materials and thicknesses, other film formation methods, and film formation conditions may also be adopted.

In addition, while the semiconductor film 14 is formed to have a tapered form (smaller than about 90 degrees with respect to the substrate 11) in this instance, this is not limitative, and the semiconductor film 14 may also be formed to be perpendicular to the substrate 11 (at a right angle with respect to the substrate 11). In this case, when the insulating film 36 is formed by oxidation as in the second embodiment, the form of the semiconductor film 14 is a rectangular form. It should be noted that, when the semiconductor film 14 is processed into a tapered form as in the above-mentioned embodiments and so forth, the whole side face thereof affects the electric field, whereas when the semiconductor film 14 is processed into a rectangular form, only a section near the lower end of the side face of the semiconductor film 14 affects the electric field.

Further, other layers than the layers described in the above-mentioned embodiment and so forth may also be included. In addition, for example, the insulating film 16 on the side wall of the semiconductor film 14 may also be formed by combining the forming method (the evaporation method and the CVD method) described in the first embodiment and the forming method (oxidation) described in the second embodiment.

It should be noted that the present technology may be configured as follows.
(1) A thin film transistor including:
   a gate electrode;
      a semiconductor film including a channel region that faces the gate electrode; and
   an insulating film provided at least at a position near an end portion on the gate electrode side of side walls of the semiconductor film.
(2) The thin film transistor according to (1), further including
   a gate insulating film between the gate electrode and the semiconductor film, wherein
   the insulating film is provided from a side wall of the semiconductor film to a surface of the gate insulating film.
(3) The thin film transistor according to (1) or (2), wherein the insulating film is provided at least in a same direction as a direction in which the gate electrode extends.
(4) The thin film transistor according to any one of (1) to (3), further including
   a pair of source and drain electrodes electrically connected to the semiconductor film, wherein
   the insulating film is interposed between an interface between the semiconductor film and the gate insulating film, and an interface between the source and drain electrodes and the gate insulating film.
(5) The thin film transistor according to any one of (1) to (4), wherein the insulating film is provided on a side face of the semiconductor film in a side wall form.
(6) The thin film transistor according to any one of (1) to (4), wherein the insulating film is provided in parallel along side faces of the semiconductor film.
(7) The thin film transistor according to any one of (1) to (4), wherein the insulating film is provided on a side face of the semiconductor film in a rectangular form.
(8) The thin film transistor according to any one of (1) to (7), wherein the insulating film has a film thickness of about 2 nm to about 300 nm both inclusive, in a width direction thereof.
(9) The thin film transistor according to any one of (1) to (8), wherein the semiconductor film has a planar dimension smaller than a planar dimension of the gate electrode, and light coming from the gate electrode side is totally shielded.
(10) The thin film transistor according to any one of (1) to (8), wherein the semiconductor film has a planar dimension greater than a planar dimension of the gate electrode, and light coming from the gate electrode side is partially shielded.
(11) The thin film transistor according to any one of (1) to (10), wherein the semiconductor film includes a channel protective film on the channel region.
(12) A method of manufacturing a thin film transistor, the method including:
   forming a gate electrode on a substrate;
   forming a semiconductor film on the gate electrode, the semiconductor film including a channel region that faces the gate electrode; and
forming an insulating film at least at a position near an end portion on the gate electrode side of side walls of the semiconductor film.
(13) The method of manufacturing the thin film transistor according to (12), wherein the insulating film is formed by a CVD method and an etch back method.
(14) The method of manufacturing the thin film transistor according to (12), wherein the insulating film is formed by oxidizing the semiconductor film.
(15) A display unit provided with a plurality of devices and a thin film transistor that drives the plurality of devices,
   the thin film transistor including:
   a gate electrode;
   a semiconductor film including a channel region that faces the gate electrode; and
   an insulating film provided at least at a position near an end portion on the gate electrode side of side walls of the semiconductor film.
(16) An electronic apparatus including a display unit provided with a plurality of devices and a thin film transistor that drives the plurality of devices,
   the thin film transistor including:
   a gate electrode;
   a semiconductor film including a channel region that faces the gate electrode; and
   an insulating film provided at least at a position near an end portion on the gate electrode side of side walls of the semiconductor film.
(17) A thin film transistor comprising:
   a substrate;
   a gate electrode on the substrate;
   a semiconductor film facing the gate electrode;
   a channel forming region in the semiconductor film;
   a pair of source and drain regions on the substrate; and
   an insulating film on at least a portion of a side face of the semiconductor film. (18) The thin film transistor according to (17) wherein the insulating film is on the entire side face of the semiconductor film.
(19) The thin film transistor according to (17) wherein the insulating film is parallel to the side face of the semiconductor film.
(20) The thin film transistor according to (17) further comprising a gate insulating film in-between the semiconductor film and the gate electrode.
(21) The thin film transistor according to (20), wherein the insulating film is located at an interface between the semiconductor film and the gate insulating film.
(22) The thin film transistor according to (17), wherein a length, x, of the gate electrode is longer than a length, y, of the semiconductor film.
(23) The thin film transistor according to (17), wherein a length, x, of the gate electrode is shorter than a length, y, of the semiconductor film.
(24) The thin film transistor according to (17), wherein the semiconductor film has a thickness of 2 nm to 300 nm, inclusive.
(25) The thin film transistor according to (17), wherein the insulting film comprises at least one of SiO2, SiN, or SiON.
(26) A display unit comprising:
   a pixel driving circuit layer;
   a light emitting device layer substrate; and
   a thin film transistor in the pixel driving circuit layer, wherein,
   the thin film transistor comprises (i) a substrate, (ii) a gate electrode facing the substrate, (iii) a semiconductor film on the gate electrode (iv) a channel forming region in the semiconductor film, (v) a pair of source and drain regions on the substrate, and (vi) an insulating film on at least a portion of the side face of the semiconductor film.
(27) A method of manufacturing a thin film transistor comprising the steps of:
   providing a substrate;
   forming a gate electrode on the substrate;
   forming a semiconductor film facing the gate electrode;
   forming an insulating film on at least a portion of a side face of the semiconductor film;
   forming a source region; and
   forming a drain region.
(28) The thin film transistor according to (17), wherein the semiconductor film comprises a polysilicon, an amorphous silicon, or an oxide which contains at least one of In, Ga, Zn, Sn, Al, and Ti as a main component.
(29) The thin film transistor according to (17) further comprising a channel protective film is on the semiconductor film.
(30) The thin film transistor according to (17) further comprising a channel protective film between the source electrode and the drain electrode, wherein each of the source electrode and the drain electrode partially overlap the protective film.

The present disclosure contains subject matter related to that disclosed in Japanese Priority Patent Application JP 2012-179520 filed in the Japan Patent Office on Aug. 13, 2012, the entire content of which is hereby incorporated by reference.

It should be understood by those skilled in the art that various modifications, combinations, sub-combinations, and alterations may occur depending on design requirements and other factors insofar as they are within the scope of the appended claims or the equivalents thereof.

### REFERENCES SIGNS LIST

1 display unit
10, 30, 40, 50, 60A to 60D thin film transistor
11 substrate
12 gate electrode
13 gate insulating film
14 semiconductor film
14C channel region
15A source electrode
15B drain electrode
16 insulating film
17 planarizing layer
18 device separating film
20 organic light emitting device
21 first electrode
22 organic layer
23 second electrode
69 channel protective film

1. A thin film transistor comprising:
a substrate;
a gate electrode on the substrate;
a semiconductor film facing the gate electrode;
a channel forming region in the semiconductor film;
a pair of source and drain regions on the substrate; and
an insulating film on at least a portion of a side face of the semiconductor film.

2. The thin film transistor according to claim 1 wherein the insulating film is on the entire side face of the semiconductor film.

3. The thin film transistor according to claim 1 wherein the insulating film is parallel to the side face of the semiconductor film.

4. The thin film transistor according to claim 1 further comprising a gate insulating film in-between the semiconductor film and the gate electrode.

5. The thin film transistor according to claim 4, wherein the insulating film is located at an interface between the semiconductor film and the gate insulating film.

6. The thin film transistor according to claim 1 wherein a length, x, of the gate electrode is longer than a length, y, of the semiconductor film.

7. The thin film transistor according to claim 1 wherein a length, x, of the gate electrode is shorter than a length, y, of the semiconductor film.

8. The thin film transistor according to claim 1 wherein the semiconductor film has a thickness of 2 nm to 300 nm, inclusive.

9. The thin film transistor according to claim 1 wherein the insulting film comprises at least one of SiO2, SiN, or SiON.

10. A display unit comprising:
a pixel driving circuit layer;
a light emitting device layer substrate; and
a thin film transistor in the pixel driving circuit layer, wherein,
the thin film transistor comprises (i) a substrate, (ii) a gate electrode facing the substrate, (iii) a semiconductor film on the gate electrode (iv) a channel forming region in the semiconductor film, (v) a pair of source and drain regions on the substrate, and (vi) an insulating film on at least a portion of the side face of the semiconductor film.

11. A method of manufacturing a thin film transistor comprising the steps of:
providing a substrate;
forming a gate electrode on the substrate;
forming a semiconductor film facing the gate electrode;
forming an insulating film on at least a portion of a side face of the semiconductor film;
forming a source region; and
forming a drain region.

12. The thin film transistor according to claim 1 wherein the semiconductor film comprises a polysilicon, an amorphous silicon, or an oxide which contains at least one of In, Ga, Zn, Sn, Al, and Ti as a main component.

13. The thin film transistor according to claim 1 further comprising a channel protective film is on the semiconductor film.

14. The thin film transistor according to claim 1 further comprising a channel protective film between the source electrode and the drain electrode, wherein each of the source electrode and the drain electrode partially overlap the protective film.
